(19) United States
(12) Patent Application Publication
(10) Pub. No.: US 2004/0245523 A1
(43) Pub. Date: Dec. 9, 2004

(54) Circular thin film transistor structure

(76) Inventors: Tean-Sen Jen, Ping Chen City (TW); Ming-Tien Lin, Lu Chou City (TW)

Correspondence Address: SUGHRUE MION, PLLC, 2100 PENNSYLVANIA AVENUE, N.W., SUITE 800, WASHINGTON, DC, 20037, US

(21) Appl. No.: 10/737,874

(22) Filed: Dec. 17, 2003

(30) Foreign Application Priority Data
Jun. 5, 2003 (TW) 92115296

(51) Int. Cl. H01L 29/04

(52) U.S. Cl. 257/59; 257/72; 257/347

(57) ABSTRACT

The present invention provides a circular thin film transistor structure that is located in the intersection of the gate line and the data line. A circular gate electrode is defined when forming the gate line. A circular source electrode and an annular drain electrode are defined when forming the data line. The circular source is located in the annular drain electrode. This structure can avoid the voltage value variation in the pixel region because of the misalignment between the source electrode and the gate electrode.

### CROSS-REFERENCE TO RELATED APPLICATIONS

This application claims benefit of Taiwanese patent application serial number 92115296, filed Jun. 5, 2003, which is herein incorporated by reference.

### BACKGROUND OF THE INVENTION

1. Field of the Invention

The present invention relates to a thin film transistor (TFT), and more particularly to a circular thin film transistor.

2. Description of the Related Art

Liquid crystal displays (LCD) have been widely applied in electrical products, such as digital watches, calculator, etc. for a long time. Moreover, with the advance of techniques for manufacture and design, thin film transistor-liquid crystal display (TFT-LCD) has been introduced into portable computers, personal digital assistants, and color televisions, as well as gradually replacing the CRT used for conventional display. The demands for TFT-LCD tend to be large in scale.

In general, a typical circuit of a liquid crystal display is illustrated in FIG. 1A, in which the LCD matrix display device commonly comprises a LCD display array 200 that further includes a plurality of display elements 50, whose enlarged diagram is shown in the FIG. 1B, arranged in a matrix of rows and columns. Switching devices (not shown in this figure) are coupled with display elements 50 to control the application of video signals thereto. Each display element 50 acts as a switching device that includes a pixel capacitor 106 and a maintenance capacitor 108 driven by a switching transistor 104, referring to FIG. 1B.

The switching transistor 104 is usually a thin-film transistor (TFT) that is deposited on a transparent substrate such as glass. The source/drain electrode of the switching transistor 104 is deposited on the glass on the same side of the display matrix as the switching transistor and is respectively connected to the capacitor electrodes of the pixel capacitor 106 and the maintenance capacitor 108. The source/drain electrode of the switching transistor 104 is connected to a column data driver (not shown in this figure) through the video data line 100 to which video signals are applied. The gate electrodes of the switching transistor 104 is coupled to a row select driver (not shown in this figure) through a scan line 102, and a scan signal is applied to turn on the switching transistor 104.

When the switching transistors 104 in a given scan line 102 are selected by the scan signals, the video signals supplied to the switching transistors 104 charge the pixel capacitors 106 and the maintenance capacitor 108 to a voltage value corresponding to the video signal on the video data line. Thus each pixel capacitor 106 with its electrodes on opposite sides of the matrix display acts as a capacitor. When a signal for a selected scan line 102 is removed, the charge in the pixel capacitor 106 is preserved until the next repetition when that scan line is again selected by a scan signal and new voltages are stored therein. Thus a picture is displayed on the matrix display by the charges stored in the pixel capacitors 106.

On the other hand, the main function of the maintenance capacitor 108 is to maintain the constancy of the voltage value applied to the pixel capacitor 106. That is, before the data stored in the pixel capacitor 106 is refreshed, the voltage applied to the pixel capacitor 106 is maintained by the maintenance capacitor 108.

FIG. 2 shows a waveform diagram for driving the thin film transistor LCD. The pixel capacitor 106 and the maintenance capacitor 108 are charged to the voltage value, V_{P}, of the corresponding video data line 100 when the scan line 102 scans the switching transistors 104 at a given T₁ time. The switching transistor 104 is turned off at the non-selective time T₂. The pixel capacitor 106 is maintained by the maintenance capacitor 108. However, the instant the switching transistor 104 is turned off, the voltage value (V_{P}) may fall by ΔV. The ΔV is related to the diffusion capacitor (C_{gs}) between the gate and source electrodes, pixel capacitor 106 (C_{LC}) and the maintenance capacitor 108 (C_{ST}). The ΔV value is shown as follows:

ΔV=V_{P}×C_{gs}/(C_{gs}+C_{LC}+C_{ST}) (1)

The ΔV value is related to the quality of the liquid crystal display. Typically, the liquid crystal display causes a flicker phenomenon if the ΔV value exceeds a specific value. This flicker phenomenon reduces the quality of the liquid crystal display. Therefore, the best method for resolving the flicker phenomenon is to reduce the ΔV value.

Accordingly, the structure of the conventional thin film transistor is illustrated in FIG. 3, in which a gate electrode 4 and the storage capacitor electrode 6 are formed on a glass substrate 2. An insulating layer 8 is formed on the substrate 2 to cover the gate electrode 4 and the storage capacitor electrode 6. An a-silicon layer 10 is formed above the insulating layer 8 and the gate electrode 4, and an n+ a-silicon layer 12 is deposited on the top surface of the a-silicon layer 10. In additional, a source/drain electrode structure 14 is formed above the n+ a-silicon layer 12. The data lines structure 16 is defined over the insulating layer 8, too, when forming the source/drain electrode structure 14. Moreover, a passivation layer 18 is formed on the top surface of glass substrate 2 to cover the a-silicon layer 10, the source/drain electrode structure 14 and the data lines structure 16. A contact hole 20 is formed on the passivation layer 18 to expose the top surface of the source/drain electrode structure 14. Then, an ITO layer 22 is formed on the passivation layer 16 to connect the source/drain electrode structure 14.

The diffusion capacitor (C_{gs}) between the gate electrode 4 and the source/drain electrode structure 14 is composed of C_{gs1} and C_{gs2}. A photolithography process is performed when forming the source/drain electrode structure 14. Therefore, once a misalignment situation happens between the gate electrode 4 and the source/drain electrode structure 14, the value of the diffusion capacitor (C_{gs}) is changed. According to equation (1), the value of ΔV also is changed to cause the flicker phenomenon.

### SUMMARY OF THE INVENTION

According to the above descriptions, the ΔV value is related to the quality of the liquid crystal display. A varying ΔV value in the liquid crystal display causes the flicker phenomenon that reduces the quality of the liquid crystal display. Therefore, a thin film transistor structure that reduces the flicker phenomenon of a liquid crystal display is required.

The ΔV is related to the diffusion capacitor (C_{gs}) between the gate electrode and the source electrode, pixel capacitor (CLC) and the maintenance capacitor. Therefore, the ΔV value is shown as follows:

ΔV=V_{P}˜×C_{gs}/(C_{gS}+C_{LC}+C_{ST})

Misalignments often happen between the gate electrode and the source/drain electrode structure. Therefore, the value of the diffusion capacitor (C_{gs}) is changed. According to the above equation, the different diffusion capacitor (C_{gs}) value changes the ΔV value, which may cause the flicker phenomenon in the liquid crystal display.

Therefore, the main object of the present invention is to provide a circular thin film transistor structure. Accordingly, the diffusion capacitor (C_{gs}) can be maintained at a fixed value, which in turn can maintain the ΔV value to improve the display quality of the liquid crystal display.

Another object of the present invention is to provide a circular thin film transistor structure with a different structure formed in the intersection of the gate line and the data line, which is different from the conventional structure that extends out the data line. Therefore, the open ratio can be improved.

Yet another object of the present invention is to provide a circular thin film transistor structure. Under the same transistor volume, this circular structure has a longer channel compared to the conventional structure. Therefore, the charge/recharge velocity of the transistor can be improved.

The present invention provides a circular thin film transistor structure. Accordingly, a circular gate electrode is defined when forming the gate line. A circular source electrode and an annular drain electrode are defined when forming the data line. The circular source electrode is located in the annular drain electrode. Therefore, the source electrode is always located in the range of the gate electrode. Even if the gate electrode and the source electrode are misaligned, the diffusion capacitor C_{gs} suffers no change that might reduce the display quality. Moreover, this structure is formed in the intersection of the gate line and the data line. Therefore, the open ratio can be improved.

On the other hand, a transparent resin with thickness about 2 μm to 5 μm or a transmitting resin with a special color, such as red, green or blue color, is used to package the circular thin film transistor of the present invention. A contact hole formed in the resin to expose the top surface of the circular source electrode. The main object of this resin is to reduce the capacitance between the ITO layer over this resin and the gate electrode or the capacitance between the ITO layer and the source electrode.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A illustrates a schematic circuit diagram of a conventional liquid crystal display;

FIG. 1B illustrate an enlarged schematic diagram of part of the circuit shown in FIG. 1A;

FIG. 2 illustrates a waveform diagram for driving the thin film transistor liquid crystal display;

FIG. 3 illustrates a schematic diagram of the conventional thin film transistor structure;

FIG. 4 illustrates a top view schematic diagram of the circular thin film transistor formed in the intersection of the data line and the gate line according to the invention;

FIG. 5 illustrates a schematic, cross-sectional view along the AA′ line in FIG. 4, of the circular thin film transistor according to the first preferred embodiment; and

FIG. 6 illustrates a schematic, cross-sectional view along the AA′ line in FIG. 4, of the circular thin film transistor according to the second preferred embodiment.

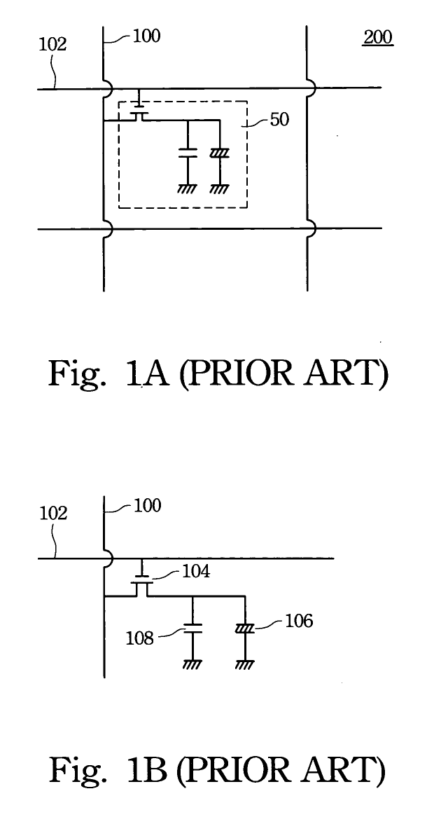

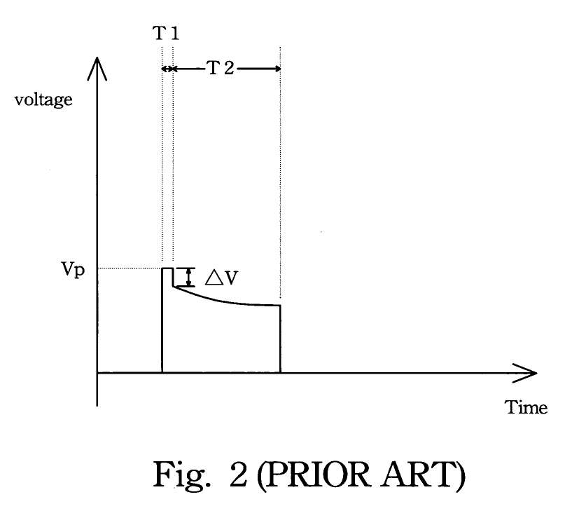

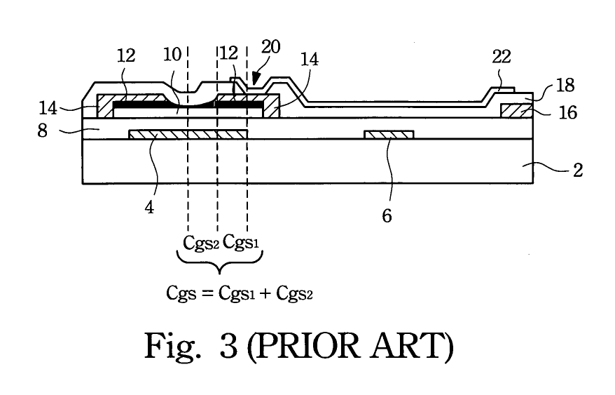

### DETAILED DESCRIPTION OF THE PREFERRED EMBODIMENT

Without limiting the spirit and scope of the present invention, the circular thin film transistor structure proposed in the present invention is illustrated with one preferred embodiment. One of ordinary skill in the art, upon acknowledging the embodiment, can apply the circular thin film transistor structure of the present invention to various liquid crystal display. Accordingly, the diffusion capacitor (C_{gs}) can be maintained at a fixed value, which can maintain the ΔV value to improve the display quality of the liquid crystal display. The circular thin film transistor structure of the present invention is not limited by the preferred embodiments described in the following.

The present invention provides a circular thin film transistor structure. The structure is formed in the intersection of the gate line and the data line, which is different from the conventional structure that extends out the data line. Therefore, the open ratio can be improved. Moreover, under the same transistor volume, this circular structure has a longer channel compared to the conventional transistor structure. Therefore, the charge/recharge velocity of the transistor can be improved. The detailed description of the present invention is as follows.

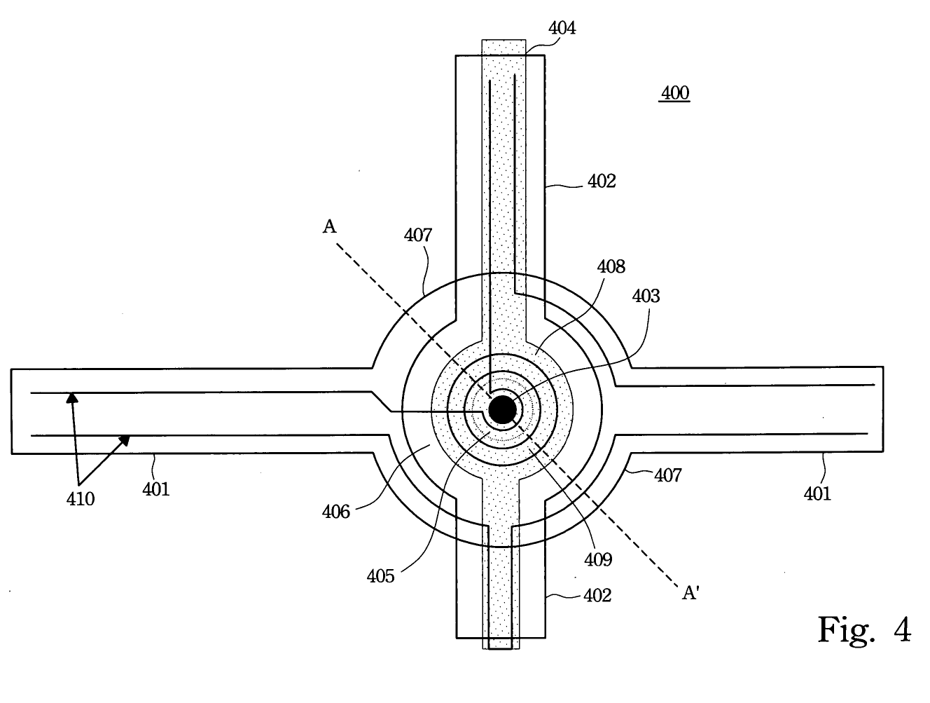

FIG. 4 illustrates a top view schematic diagram of the circular thin film transistor formed in the intersection of the data line and the gate line according to the present invention. According to the preferred embodiment, a first metal layer is formed over a glass substrate. The first metal layer is used as the circular gate electrode 407 of the circular thin film transistor 400. It is noted that a data line structure 401 is also defined on the glass substrate when forming the circular gate electrode 407. Next, an insulating layer (not shown in the figure) is formed over the glass substrate to cover the circular gate electrode 407. An amorphous-silicon layer 404 is formed over the insulating layer and the circular gate electrode 407. This amorphous-silicon layer 404 has a circular amorphous-silicon structure 408 over the circular gate electrode 407 and extends in a direction perpendicular to the gate line 401. This circular amorphous-silicon structure 408 over the circular gate electrode 407 is used as the source/drain region of the circular thin film transistor 400.

Next, a second metal layer is formed over the amorphous-silicon layer 404 and the circular amorphous-silicon structure 408. An insulating layer is used to isolate the first metal layer and the second metal layer. This second metal layer is used as the circular source electrode 405 and the annular drain electrode 406 of the thin film transistor 400. It is noted that a data line structure 402 over the top surface of the insulating layer is also defined when forming the circular source electrode 405 and the annular drain electrode 406. The annular drain electrode 406 surrounds and does not contact the source electrode 405. In other words, a annular channel 409 is located between them.

Next, a passivation layer and a transparent resin (not shown in the figure) is deposited over the glass substrate to cover the circular source electrode 405, the annular drain electrode 406, the amorphous-silicon layer 404 and the data line structure 402. The passivation layer and the transparent resin both have a contact hole 403 to expose the top surface of the circular source electrode 405. Finally, an ITO layer is formed over the transparent resin to serve as the transparent electrode 410. This transparent electrode 410 is connected to the circular source electrode 405 through the contact hole 403. The circular thin film transistor of the present invention is finished. The main object of the transparent resin is used to reduce the capacitor between the transparent electrode 410 and the first metal layer and the capacitor between the transparent electrode 410 and the second metal layer.

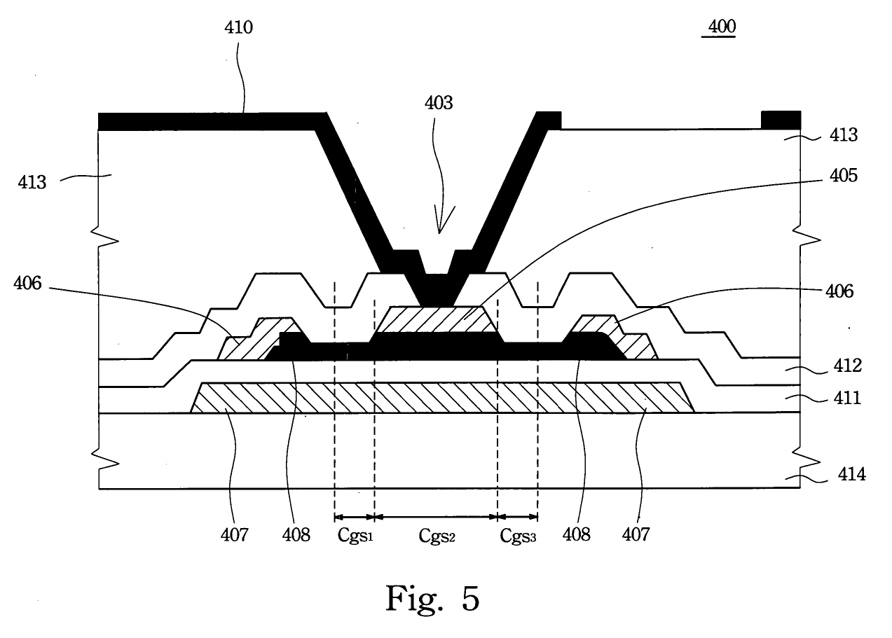

FIG. 5 illustrates a cross-sectional view along the AA′ line in FIG. 4, of the circular thin film transistor according to the first preferred embodiment. In this preferred embodiment, glass, quartz, or the like is used as a transparent insulator substrate 414. Next, a sputtering method is used to form a first metal layer on the transparent insulator substrate 414 at a temperature of about 25° C. to 100° C. The thickness of the first metal layer is typically about 1000 to 5000 angstroms. The first metal layer is used to define the gate structure and the gate line structure. Typically, the first metal layer can be chosen from the group of chromium(Cr), tungsten(W), titanium(Ti), tantalum(Ta), molybdenum(Mo), aluminum(Al), copper(Cu) and alloy. A Cr/Al composition layer can also be used as the first metal layer. Then, the first metal layer is patterned to define the circular gate electrode 407 over the transparent insulator substrate 414. In a preferred embodiment, a mask layer is first formed over the first metal layer. Then, a RIE method is used to define the pattern.

Still referring to FIG. 5, an insulating layer 411 is formed on the circular gate electrode 407 and the transparent insulator substrate 414. The insulating layer 411 can be oxide, nitride, oxynitride, or the like. In this preferred embodiment, the silicon oxide layer or the nitride layer can be formed by using plasma chemical vapor deposition (PCVD) process at a temperature of about 330° C., and the reaction gases are SiH₄, NH₃, N₂, N₂O or SiH₂Cl₂, NH₃, N₂, N₂O. The thickness of the insulating layer 411 is typically about 3000 to 4000 angstroms.

Next, an active layer is deposited on the insulating layer 411 to serve as the channel of the thin film transistor devices by conventional methods, in which the active layer can be made of amorphous-silicon. In a preferred embodiment, the thickness of the amorphous-silicon layer 408 is typically about 2000 to 3000 angstroms. The appearance of the amorphous-silicon layer 408 of the thin film transistor 400 is circular. Next, a contact layer (not shown in the figure) is formed on a top surface of the amorphous-silicon layer 408 to serve as an interface between the circular amorphous-silicon layer 408 and source/drain structures formed later. In an embodiment, the contact layer is formed of n+ doped amorphous-silicon.

Next, a second metal layer is formed over the circular amorphous-silicon layer 408 and the insulating layer 411 to define the source/drain electrode structure and the other conductive devices. Typically, the second metal layer can be chosen from the group of chromium(Cr), tungsten(W), titanium(Ti), tantalum(Ta), molybdenum(Mo), aluminum(Al), copper(Cu) and alloy. A Cr/Al composition layer can also be used as the first metal layer. A lithography step is performed on the second metal layer to define the pattern of the source electrode 405 and the drain electrode 406. The appearance of the source electrode 405 is a circular structure. The appearance of the drain electrode 406 is an annular structure. The annular drain electrode 406 surrounds and does not contact the circular source electrode 405. Therefore, a channel is formed between them.

Next, a passivation layer 412 is formed on the annual drain electrode 406, circular source electrode 405, circular amorphous-silicon 408 and the insulating layer 411. The passivation layer 118 can be oxide, nitride, or oxynitride. In a preferred embodiment, the oxide layer with a thickness of about 2000 to 4000 angstroms can be formed by chemical vapor deposition at about 330° C. The reaction gases for forming the silicon oxide or nitride layer can be SiH₄, NH₃, N₂, N₂O or SiH₂Cl₂, NH₃, N₂, and N₂O. Then, a transparent resin 413 with a thickness of about 2 μm to 6 μm is formed over the passivation layer 412. The material of the transparent resin 413 is High Aperture Ratio(HAR) resin or Color Filter on Array (COA) resin. The main object of the transparent resin 413 is to reduce the capacitance between the transparent conducting layer and the first metal layer and the capacitance between the transparent conducting layer and the second metal layer.

Then, an etching step is performed to form a contact hole 403 on the passivation layer 412 and the transparent resin 413 for exposing the top surfaces of the circular source electrode 405. Next, a transparent conducting layer 410 is formed on the transparent resin 413 and the exposed top surfaces of the circular source electrode 405, in order to connect with the circular source electrode 405 electrically. In a preferred embodiment, an indium tin oxide (ITO) layer with thickness of about 200 to 800 angstroms is formed at a temperature of about 25° C. by performing a sputtering step, and serves as the transparent conducting layer 410.

The present invention can provide various benefits. First, referring to FIG. 4 and FIG. 5, according to the structure of the present invention, the circular thin film transistor 400 is formed in the intersection of the gate line 401 and the data line 402, which is different from the conventional structure that extends out the data line 402. Therefore, the open ratio can be improved. Moreover, as shown in the FIG. 5, the capacitor (C_{gs}) between the source electrode and the gate electrode of the circular thin film transistor is composed of C_{gs1}, C_{gs2} and C_{gs3}. Accordingly, even if gate electrode 407 and source electrode 405 are misaligned, the value of the diffusion capacitor (C_{gs}) is not changed because the circular source electrode 405 is always located in the range of the circular gate electrode 407. Therefore, the display quality of the liquid crystal display can be improved.

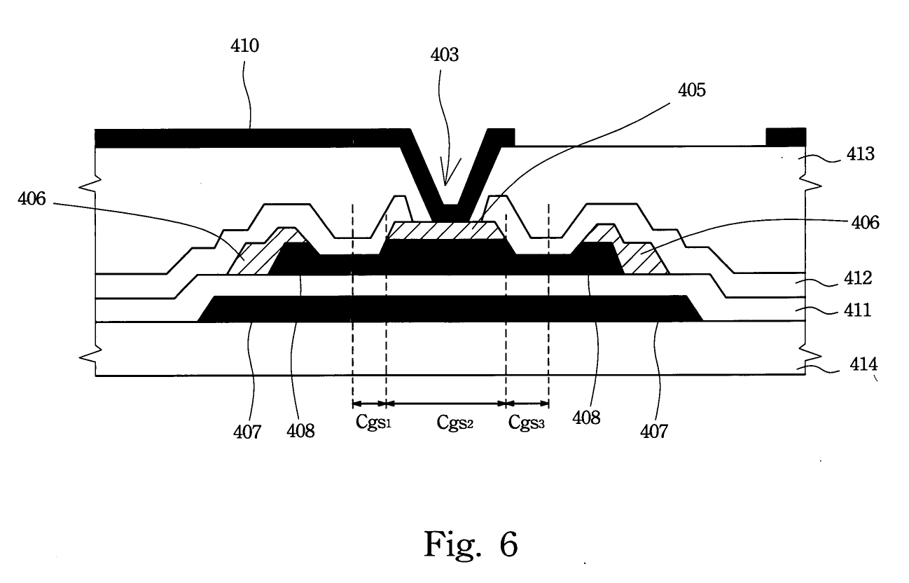

FIG. 6 illustrates a cross-sectional view along the AA′ line in FIG. 4, of the circular thin film transistor in according to the second preferred embodiment. The main difference between FIG. 5 and FIG. 6 is the design of the contact hole 403.

As is understood by a person skilled in the art, the foregoing preferred embodiments of the present invention are illustrative of the present invention rather than limiting of the present invention. It is intended that this description cover various modifications and similar arrangements included within the spirit and scope of the appended claims, the scope of which should be accorded the broadest interpretation so as to encompass all such modifications and similar structure.

1. A circular thin film transistor structure formed in a transparent substrate, said structure comprising:
a first metal line with a first circular part located over said transparent substrate and arranged in a first direction;
an insulating layer located over said first metal line;
a active layer with a second circular part located over said insulator later, wherein said second circular part is located over said first circular part;
a second metal line with an annular part located over said insulating layer and said active layer and arranged in a second direction, wherein said annular part has a hollow region and is located over said first circular part;
a circular metal layer located over said active layer and in said hollow region;
a passivation layer located over said insulating layer, said active layer, said second metal line and said circular metal layer, wherein an opening hole is located in said passivation layer to expose a top surface of said circular metal layer;
a transparent resin layer located over said passivation layer, wherein a contact hole is located in said transparent resin layer to expose the top surface of said circular metal layer; and
a transparent electrode layer located over said transparent resin and in contact with said circular metal layer through said contact hole.

2. The circular thin film transistor structure according to claim 1, wherein said active layer is an amorphous-silicon layer or a poly-silicon layer.

3. The circular thin film transistor structure according to claim 1, wherein the thickness of said transparent resin is about 1 μm to 6 μm.

4. The circular thin film transistor structure according to claim 1, wherein said insulating layer is a silicon-oxide layer, silicon-nitride layer or silicon-oxynitride layer.

5. The circular thin film transistor structure according to claim 1, wherein said first direction is perpendicular to said second direction.

6. The circular thin film transistor structure according to claim 1, wherein said first metal line is used as the gate line.

7. The circular thin film transistor structure according to claim 1, wherein said second metal line is used as the data line.

8. The circular thin film transistor structure according to claim 1, wherein said first circular part serves as the gate electrode of said circular thin film transistor.

9. The circular thin film transistor structure according to claim 8, wherein said second circular part serves as the active region of said circular thin film transistor.

10. The circular thin film transistor structure according to claim 1, wherein said annular part serves as the drain electrode of said circular thin film transistor.

11. The circular thin film transistor structure according to claim 1, wherein said circular metal layer serves as the source electrode of said circular thin film transistor, and said circular metal layer and said second metal layer are formed at the same time.

12. The circular thin film transistor structure according to claim 1, wherein said opening hole of said passivation layer is less than said contact hole of said transparent resin.

13. The circular thin film transistor structure according to claim 1, wherein said opening hole of said passivation layer is larger than said contact hole of said transparent resin.
